(19) United States
(12) Patent Application Publication
(10) Pub. No.: US 2026/0324501 A1
(43) Pub. Date: Oct. 15, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Min-Shiang Hsu, Kaohsiung City (TW); Yu-Ping Wang, Hsinchu City (TW); Chien-Ting Lin, Tainan City (TW)

(73) Assignee: UNITED MICROELECTRONICS CORP., Hsin-Chu City (TW)

(21) Appl. No.: 19/207,427

(22) Filed: May 14, 2025

(30) Foreign Application Priority Data
Apr. 15, 2025 (TW) 114114165

(51) Int. Cl. H10W 90/00; H10W 44/00; H10W 70/05; H10W 70/60; H10W 70/65; H10W 70/69; H10W 80/00

(52) U.S. Cl. CPC H10W 90/00; H10W 44/601; H10W 70/095; H10W 70/611; H10W 70/65; H10W 70/69; H10W 90/401; H10W 80/312; H10W 80/327; H10W 90/724; H10W 90/794

(57) ABSTRACT

A method for fabricating a semiconductor device includes the steps of first providing a first interposer having first passive devices therein, providing a second interposer having first active devices therein, bonding the first interposer and the second interposer to form a first stack structure, and then bonding dies having different functionalities on the second interposer. Preferably, micro bumps are disposed between the dies and the second interposer, hybrid bonds are disposed between the first interposer and the second interposer, and the first passive devices include deep trench capacitors.

### BACKGROUND OF THE INVENTION

### 1. Field of the Invention

The invention relates to a method for fabricating semiconductor device, and more particularly, to a method of stacking a passive device interposer and an active device interposer to form a stack structure.

### Description of the Prior Art

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating a semiconductor device includes the steps of first providing a first interposer having first passive devices therein, providing a second interposer having first active devices therein, bonding the first interposer and the second interposer to form a first stack structure, and then bonding dies having different functionalities on the second interposer. Preferably, micro bumps are disposed between the dies and the second interposer, hybrid bonds are disposed between the first interposer and the second interposer, and the first passive devices include deep trench capacitors.

According to another aspect of the present invention, a semiconductor device includes a first stack structure having a first interposer and a second interposer bonded to the first interposer, in which the first interposer includes first passive devices therein and the second interposer includes first active devices therein.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a structural view of a semiconductor device according to an embodiment of the present invention.

FIG. 2 illustrates a structural view of a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

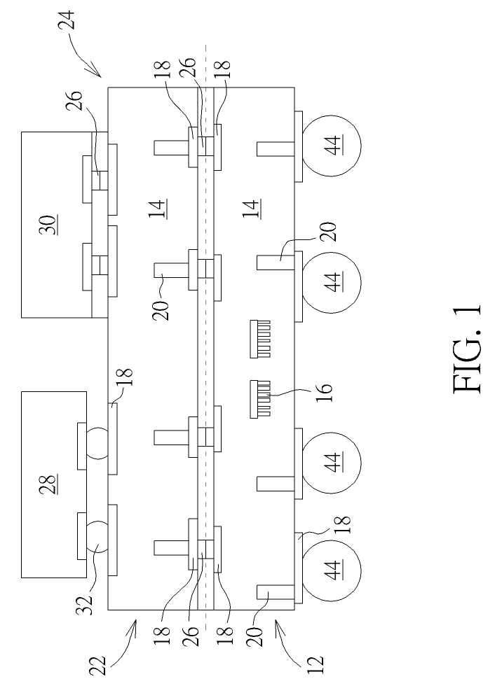

Referring to FIG. 1, FIG. 1 illustrates a structural view of a semiconductor device according to an embodiment of the present invention. As shown in FIG. 1, a first interposer 12 made of semiconductor material is provided, in which the first interposer 12 includes a substrate 14 made of semiconductor materials as the substrate 14 could also be made of semiconductor substrate material including but not limited to for example silicon substrate or wafer, epitaxial silicon substrate, silicon carbide substrate or even a silicon-on-insulator (SOI) substrate, which are all within the scope of the present invention. In this embodiment, the first interposer 12 preferably includes a plurality of passive devices such as deep trench capacitors (DTCs) 16, in which the passive devices could be fabricated according to 65 nm or 130 nm fabrication nodes.

According to an embodiment of the present invention, the first interposer 12 could include interlayer dielectric (ILD) layer or inter-metal dielectric (IMD) layer disposed on the substrate 14 and metal interconnections 18 disposed in the IMD layer, in which the topmost metal interconnection 18 could be used as connecting junctions such as hybrid bonds or direct bond interconnects (DBIs) 26 for connecting to DBIs 26 of another interposer or wafer in the later process. Additionally, through-silicon vias (TSVs) 20 could also be formed in the substrate 14 of the first interposer 12 for connecting to passive devices on the substrate 14 as well as bumps in the later process. In this embodiment, the ILD layer and the IMD layer could include oxides including but not limited to for example tetraethyl orthosilicate (TEOS) and the metal interconnections 18, DBIs 26, and TSVs 20 could include Al, Cr, Cu, Ta, Mo, W, or combination thereof.

Next, a second interposer 22 made of semiconductor material is provided. Similar to the first interposer 12, the second interposer 22 includes a substrate 14 made of semiconductor materials as the substrate 14 could also be made of semiconductor substrate material including but not limited to for example silicon substrate or wafer, epitaxial silicon substrate, silicon carbide substrate or even a silicon-on-insulator (SOI) substrate, which are all within the scope of the present invention. In this embodiment, the second interposer 22 includes a plurality of active devices (not shown) such as static random access memories (SRAMs), medium voltage (MV) devices, high voltage (HV) devices, pixel circuits, low-voltage (LV) devices for LV driving circuits, and/or graphics process unit (GPU), in which the active devices could be fabricated according to 28 nm, 22 nm, 14 nm, or 12 nm fabrication nodes.

Next, a front end of line (FEOL) and a back end of line (BEOL) fabrication processes could be conducted on the first interposer 12. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers and metal interconnections 18 on the aforementioned active devices and/or passive devices.

If a MOS transistor were to be fabricated, the FEOL process could include the steps of forming a gate structure on the substrate 14, forming a spacer (not shown) adjacent to sidewalls of the gate structure, and forming a source/drain region in the substrate 14 adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate 14 to cover the MOS transistor or other active devices, and then a contact plug formation and metal interconnect process from BEOL process could be conducted to form a plurality of contact plugs in the ILD layer for connecting the source/drain region and the gate structure, an inter-metal dielectric (IMD) layer disposed on the ILD layer, and metal interconnections 18 in the IMD layer for connecting the contact plugs, in which the topmost metal interconnection 18 on front side of the second interposer 22 could be used as connecting junctions such as direct bond interconnects (DBIs) 26 for connecting to DBIs 26 of another interposer in the later process. In this embodiment, the ILD layer and the IMD layer could include oxides including but not limited to for example tetraethyl orthosilicate (TEOS) and the contact plugs, the metal interconnections 18, and DBIs 26 could include Al, Cr, Cu, Ta, Mo, W, or combination thereof. Preferably, through-silicon vias (TSVs) 20 are also formed in the substrate 14 of the second interposer 22 to connect to the active devices on the substrate 14.

It should be noted that according to an embodiment of the present invention, the first interposer 12 as disclosed previously includes passive devices while the second interposer 22 includes active devices. Specifically, the first interposer 12 does not include other devices such as active devices except passive devices while the second interposer 22 does not include other devices such as passive devices except active devices.

Next, a hybrid bonding process could be conducted to bond the first interposer 12 and second interposer 22 for forming a stack structure. Preferably, the bonding process could be accomplished by first reversing the second interposer 22 so that the front side of the second interposer 22 or the exposed surface of the metal interconnections 18 is facing toward the front side of the first interposer 12 or the exposed surface of the metal interconnections 18, and then performing a thermal treatment process to directly bond the two interposers 12, 22 by directly contacting the metal interconnections 18 on the first interposer 12 and second interposer 22 for forming DBIs 26 or hybrid bonds.

Next, a plurality of bumps 44 or solder balls are bonded to the metal interconnections 18 on the bottom of the first interposer 12 and then a plurality of dies 28, 30 having different functionalities and diced through a dicing process are bonded onto the second interposer 22, in which the dies 28, 20 could be connected to the second interposer 22 by micro bumps 32 or DBIs 26 depending on the nature of the product. For instance, the die 28 on the left could be bonded to the second interposer 22 through micro bumps 32 while the die 30 on the right could be bonded to the second interposer 22 by DBIs 26. In this embodiment, the dies 28, 30 could include high bandwidth memory (HBM) dies, radio frequency integrated circuit (RFIC) dies, power amplifier (PA) dies, or high electron mobility transistors (HEMTs) commonly fabricated from III-V semiconductors such as gallium nitride (GaN).

It should be noted that even though the two interposers 12, 22 are stacked in the manner that the passive devices are disposed on the bottom interposer while the active devices are disposed on the top interposer, according to other embodiment of the present invention, it would also be desirable to reverse the position of the passive devices and active devices by placing the active devices on the bottom interposer and the passive devices on the top interposer, which is also within the scope of the present invention.

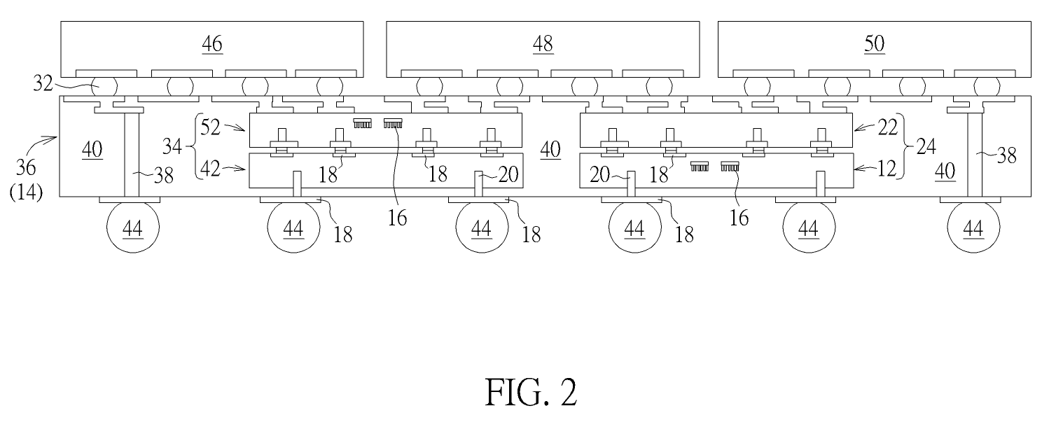

Referring to FIG. 2, FIG. 2 illustrates a structural view of a semiconductor device according to an embodiment of the present invention. For better connection between previous embodiment and t embodiment, same elements from both embodiments are labeled with same numberings. As shown in FIG. 2, a carrier or carrier substrate 36 is provided, in which the carrier substrate 36 similar to the aforementioned interposers could include a substrate 14 made of semiconductor materials as the substrate 14 could also be made of semiconductor substrate material including but not limited to for example silicon substrate, epitaxial silicon substrate, silicon carbide substrate or even a silicon-on-insulator (SOI) substrate, which are all within the scope of the present invention. According to yet other embodiment of the present invention, the carrier substrate 36 could also include silicon, silicon carbide (SiC), or glass. In contrast to the first interposer 12 and second interposer 22 having active devices and/or passive devices fabricated through FEOL and BEOL process thereon, the carrier substrate 36 is preferably a blank substrate having no active devices and/or passive devices thereon.

Next, a patterned dielectric material (not shown) or molding material is formed on the carrier substrate 36, and then a plurality of through molding vias (TMV) 38 are formed in the openings of the patterned dielectric material or molding material, in which the TMVs 38 could include Al, Cr, Cu, Ta, Mo, W, or combination thereof.

Next, two stack structures 24, 34 are provided, in which each of the stack structures 24, 34 is formed by stacking a passive device interposer and an active device interposer disclosed from the previous embodiment. Specifically, the stack structure 24 includes a first interposer 12 and a second interposer 22 from the aforementioned embodiment and the stack structure 34 includes a third interposer 42 and a fourth interposer 52, in which the first interposer 12 being a passive device interposer having multiple passive devices and metal interconnections 18 connected to the passive devices while the second interposer 22 being an active device interposer having a plurality of active devices and metal interconnections 18 connected to the active devices.

In contrast to the stack structure 24 formed by stacking passive devices on the lower level and active devices on the upper level, the stacking manner of passive devices and active devices in the stack structure 34 is preferably opposite to that of the stack structure 24. For instance, the third interposer 42 is preferably an active device interposer having a plurality of active devices and metal interconnections 18 connected to the active devices while the fourth interposer 52 is a passive device interposer having a plurality of passive devices such as DTCs and metal interconnections connected to the passive devices, in which the first interposer 12 and the fourth interposer 52 could be fabricated according to same process while having same device elements and the second interposer 22 and the third interposer 42 could be fabricated according to same process while having same device elements. In other words, the passive devices on the lower level of the stack structure 24 and the active devices on the lower level of the stack structure 34 are on the same level and the active devices on the upper level of the stack structure 24 and the passive devices on the upper level of the stack structure 34 are on the same level.

Next, the two stack structures 24, 34 are bonded onto the carrier substrate 36, and then a molding layer 40 is formed around the two stack structures 24, 34 and the TMVs 38. According to an embodiment of the present invention, the molding layer 40 could include organic or inorganic material such as oxides of fluorinated silicate glass (FSG). Moreover, the molding layer 40 could also include polymers such as thermosetting polymers, thermoplastic polymers, or combination thereof. Furthermore, the molding layer 4 could include plastic materials, epoxy resin, polyimide, polyethylene terephthalate (PET), polyvinyl chloride, (PVC), polymethyl methacrylate (PMMA), polymers including filler, or combination thereof.

Next, a plurality of bumps 44 or solder balls are bonded to the TMVs 38 and the two stack structures 24, 34 and then a plurality of dies 46, 48, 50 having different functionalities and diced through a dicing process are bonded onto the carrier substrate 36. It should be noted that even though the dies 46, 48, 50 are bonded to the carrier substrate 36 by micro bumps 32, according to other embodiment of the present invention, it would also be desirable to connect the dies 46, 48, 50 and the carrier substrate 36 through hybrid bonding or DBI depending on the specification of the dies, which are all within the scope of the present invention. In this embodiment, the dies 46, 48, 50 could include high bandwidth memory (HBM) dies, radio frequency integrated circuit (RFIC) dies, power amplifier (PA) dies, or high electron mobility transistors (HEMTs) commonly fabricated from III-V semiconductors such as gallium nitride (GaN).

Overall, the present invention discloses an approach of using hybrid bonding or DBI for vertically connecting two interposers, in which the interposers include passive devices or active devices respectively. For instance, the first interposer 12 from FIG. 1 is preferably a passive device interposer having only passive devices thereon while the second interposer 22 is an active device interposer having only active devices thereon. By vertically stacking the two interposers having passive devices and active devices individually, the present invention is able to effectively lower power consumption, achieve higher input-output count and bandwidth, and produce chips with smaller form factor and die thickness.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a first interposer having first passive devices therein;
providing a second interposer having first active devices therein; and
bonding the first interposer and the second interposer to form a first stack structure.

2. The method of claim 1, further comprising bonding dies having different functionalities on the second interposer.

3. The method of claim 2, further comprising forming micro bumps between the dies and the second interposer.

4. The method of claim 1, further comprising forming direct bond interconnects between the first interposer and the second interposer.

5. The method of claim 1, wherein the first passive devices comprise deep trench capacitors.

6. The method of claim 1, further comprising:
providing a third interposer having second active devices therein;
providing a fourth interposer having second passive devices therein; and
bonding the third interposer and the fourth interposer to form a second stack structure.

7. The method of claim 6, further comprising:
providing a carrier substrate;
forming through molding vias in the carrier substrate;
bonding the first stack structure and the second stack structure on the carrier substrate; and
forming a molding layer around the first stack structure and the second stack structure.

8. The method of claim 1, wherein the first interposer comprises a silicon wafer.

9. A semiconductor device, comprising:
a first stack structure comprising:
a first interposer having first passive devices therein; and
a second interposer bonded to the first interposer, wherein the second interposer comprises first active devices therein.

10. The semiconductor device of claim 9, further comprising dies having different functionalities on the second interposer.

11. The semiconductor device of claim 10, further comprising micro bumps between the dies and the second interposer.

12. The semiconductor device of claim 9, further comprising direct bond interconnects between the first interposer and the second interposer.

13. The semiconductor device of claim 9, wherein the first passive devices comprise deep trench capacitors.

14. The semiconductor device of claim 9, further comprising:
a second stack structure comprising:
a third interposer having second active devices therein;
a fourth interposer bonded to the third interposer, wherein the fourth interposer comprises second passive devices therein; and
direct bond interconnects connecting the third interposer and the fourth interposer.

15. The semiconductor device of claim 14, further comprising:
a carrier substrate;
through molding vias in the carrier substrate;
the first stack structure and the second stack structure on the carrier substrate; and
a molding layer around the first stack structure and the second stack structure.

16. The semiconductor device of claim 9, wherein the first interposer comprises a silicon wafer.

17. The semiconductor device of claim 9, wherein the second interposer comprises a silicon wafer.
